(19) United States
(12) Patent Application Publication
(10) Pub. No.: US 2025/0351492 A1
(43) Pub. Date: Nov. 13, 2025

(54) CHANNEL OPTIMIZATION FOR NANOSHEET TECHNOLOGY

(71) Applicant: INTERNATIONAL BUSINESS MACHINES CORPORATION, ARMONK, NY (US)

(72) Inventors: Mohammad Hasanuzzaman, Niskayuna, NY (US); Jingyun Zhang, Albany, NY (US)

(21) Appl. No.: 18/658,953

(22) Filed: May 8, 2024

(51) Int. Cl. H01L 29/08; H01L 29/06; H01L 29/423; H01L 29/66; H01L 29/775; H01L 29/786

(52) U.S. Cl. CPC H10D 62/151; H10D 30/43; H10D 30/6735; H10D 30/6757; H10D 62/121; H10D 64/017

(57) ABSTRACT

A method of method of fabricating a semiconductor device includes providing a semiconductor structure having a sheet of vertically stacked formations including alternating semiconductor layers and sacrificial layers, surrounded by a layer of dummy gate material. The sacrificial layers are removed from the sheet leaving empty channels between the semiconductor layers. A gate oxide is deposited in the empty channels. The gate oxide wraps around the semiconductor layers in the sheet and defines layers of gate oxide. The layers of gate oxide are etched inward from a space between the vertically stacked formations, forming pockets between the layers of semiconductor. A dielectric spacer is deposited into the pockets. A source and drain formation is deposited into the space between the vertically stacked formations. The layer of dummy gate material is removed. The layers of gate oxide are removed. A gate is formed in contact with the semiconductor layers.

### BACKGROUND

### Technical Field

The present disclosure generally relates to semiconductor device fabrication, and more particularly, to channel optimization for nanosheet technology.

### Description of the Related Art

In semiconductor device manufacture, nanosheet technology can form stacks of semiconductor channels into pillars that provide multiple channels through which signals can travel. Some current processes form a mandrel where the gate material wraps around layers of the semiconductor sheets. Some current techniques use epitaxial growth to form the source and drain that operates in conjunction with the nanosheet style semiconductor channels and wrap-around gate.

The current device fabrication processes use for example, SiGe(B) source/drain junctions formed by the selective etching of silicon followed by selective epitaxial growth of in situ heavily boron doped silicon germanium. The concept is beneficial compared to conventional ion implanted junctions, since dopant activation above the solid solubility in silicon can be obtained. One of inherent phenomena that occurs during the epitaxial growth stage is the migration of dopants into the semiconductor material of channels. While doping may have positive effects for the source and drain, doping material may mitigate some of the performance in the semiconductor channels.

### SUMMARY

According to an embodiment of the present disclosure, a semiconductor chip device is provided. The semiconductor device includes a substrate. A source and drain are on top of the substrate. The source and drain comprise a doped silicon germanium epitaxy. A plurality of vertically stacked semiconductor channels are positioned adjacent the source and drain. A plurality of silicon dioxide layers are positioned between the vertically stacked silicon-based channels.

According to an embodiment of the present disclosure, a method of fabricating a semiconductor device includes providing a semiconductor structure having a sheet of a plurality of vertically stacked formations including alternating semiconductor layers and sacrificial layers, surrounded by a layer of dummy gate material. The sacrificial layers are removed from the sheet leaving empty channels between the semiconductor layers. A gate oxide is deposited in the empty channels. The gate oxide wraps around the semiconductor layers. The layers of gate oxide are etched inward from a space between the vertically stacked formations, forming pockets between the semiconductor layers. A dielectric spacer is deposited into the pockets. A source and drain formation is deposited into the space between the vertically stacked formations. The layer of dummy gate material is removed. The layers of gate oxide are removed. A gate is formed in contact with the semiconductor layers.

According to another embodiment of the present disclosure, a method of controlling a flow of dopants into channels of a semiconductor device is provided. The method includes providing a semiconductor structure having a sheet of a plurality of vertically stacked formations including a plurality of semiconductor channels and sacrificial material wrapped around the semiconductor channels. The sacrificial material is removed from the vertically stacked formations leaving empty channels between the semiconductor channels. Layers of a gate oxide are deposited into the empty channels. The layers of gate oxide wrap around the semiconductor channels in the sheet. A source and drain epitaxy is deposited into the space between the vertically stacked formations. The source and drain epitaxy includes a dopant. A rate of diffusion of the dopant into the semiconductor channels is slowed by a presence of the gate oxide.

The techniques described herein may be implemented in a number of ways. Example implementations are provided below with reference to the following figures.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1A is a cross-sectional schematic view of starting formation for a semiconductor device under process along the line A-A′ of FIG. 1C, consistent with embodiments of the present disclosure.

FIG. 1B is a transverse cross-sectional view of the formation of FIG. 1A, along the line B-B′ of FIG. 1C.

FIG. 1C is a legend for axes in a top view of the semiconductor device under process, consistent with embodiments.

FIG. 2A is a cross-sectional schematic view of the device after a channel release, consistent with embodiments of the present disclosure.

FIG. 2B is a cross-sectional schematic view of the device after a channel release, consistent with embodiments of the present disclosure.

FIG. 3A is a cross-sectional schematic view of the device after gate oxide deposition, consistent with embodiments of the present disclosure.

FIG. 3B is a cross-sectional schematic view of the device after gate oxide deposition, consistent with embodiments of the present disclosure.

FIG. 4A is a cross-sectional schematic view of the device after removal of gate oxide, consistent with embodiments of the present disclosure.

FIG. 4B is a cross-sectional schematic view of the device after removal of gate oxide, consistent with embodiments of the present disclosure.

FIG. 5A is a cross-sectional schematic view of the device after deposition of an inner spacer, consistent with embodiments of the present disclosure.

FIG. 5B is a cross-sectional schematic view of the device after deposition of an inner spacer, consistent with embodiments of the present disclosure.

FIG. 6A is a cross-sectional schematic view of the device after etch back an inner spacer, consistent with embodiments of the present disclosure.

FIG. 6B is a cross-sectional schematic view of the device after etch back an inner spacer, consistent with embodiments of the present disclosure.

FIG. 7A is a cross-sectional schematic view of the device after deposition of a doped source and drain epitaxy, consistent with embodiments of the present disclosure.

FIG. 7B is a cross-sectional schematic view of the device after deposition of a doped source and drain epitaxy, consistent with embodiments of the present disclosure.

FIG. 8A is a cross-sectional schematic view of the device after deposition of a doped source and drain epitaxy diffused into semiconductor channels, consistent with embodiments of the present disclosure.

FIG. 8B is a cross-sectional schematic view of the device after deposition of a doped source and drain epitaxy diffused into semiconductor channels, consistent with embodiments of the present disclosure.

FIG. 9A is a cross-sectional schematic view of the device after removal of a dummy gate material, consistent with embodiments of the present disclosure.

FIG. 9B is a cross-sectional schematic view of the device after removal of a dummy gate material, consistent with embodiments of the present disclosure.

FIG. 10A is a cross-sectional schematic view of the device after removal of gate oxide from between the semiconductor channels, consistent with embodiments of the present disclosure.

FIG. 10B is a cross-sectional schematic view of the device after removal of gate oxide from between the semiconductor channels, consistent with embodiments of the present disclosure.

FIG. 11A is a cross-sectional schematic view of the device after trimming the thickness the semiconductor channels, consistent with embodiments of the present disclosure.

FIG. 11B is a cross-sectional schematic view of the device after trimming the thickness the semiconductor channels, consistent with embodiments of the present disclosure.

FIG. 12A is a cross-sectional schematic view of the device after forming the gate region, consistent with embodiments of the present disclosure.

FIG. 12B is a cross-sectional schematic view of the device after forming the gate region, consistent with embodiments of the present disclosure.

FIG. 13A is a cross-sectional schematic view of the device after forming metal contacts, consistent with embodiments of the present disclosure.

FIG. 13B is a cross-sectional schematic view of the device after forming metal contacts, consistent with embodiments of the present disclosure.

### DETAILED DESCRIPTION

### Overview

In conventional pillar type device formation processes, controlling the doping leakage into semiconductor channels can be a challenge. Some current processes wrap a gate oxide around a nanosheet stack of semiconductor channels. When the source and drain epitaxy is deposited, the gate oxide sits atop the top semiconductor channel. The gate oxide contributes to segregation of active dopants into the semiconductor channel. However, the middle and bottom channels below the top sheet have more boron doping leaking into their semiconductor material during the conventional process than the top channel.

In general, the subject disclosure describes a process of forming a semiconductor device with a pillar-based mandrel cut that mitigates doping in all semiconductor channels leading to steeper junction and improved device performance. The process wraps a gate oxide around the semiconductor substrate prior to source and drain epitaxial deposition. As will be appreciated, boron doping related characteristics are improved over conventional techniques leading to for example, approximately triple the reduction in overall device channel doping. In addition, the net device performance at iso leakage can be boosted by more than 10% for pillar type semiconductor devices.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, in order to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the direction of the Figures being described. Since components of embodiments of the disclosure can be positioned in a number of different directions, the directional terminology is used for purposes of illustration and is in no way limiting. Thus, it will be understood that the spatially relative terminology is intended to encompass different directions of the device in use or operation in addition to the direction depicted in the figures. For example, if the device in the figures is turned over, elements described as “below” or “beneath” other elements or features would then be oriented “above” the other elements or features. Thus, for example, the term “below” can encompass both an orientation that is above, as well as, below. Similarly, an element described as “on top of” of another element may mean either that the element is positioned above and is not necessarily in direct contact with the underlying element. The device may be otherwise oriented (rotated 90 degrees or viewed or referenced at other directions) and the spatially relative descriptors used herein should be interpreted accordingly.

As used herein, the terms “lateral”, “planar”, and “horizontal” describe an orientation parallel to a first surface of a chip or substrate. In the disclosure herein, the “first surface” may be the top layer of a semiconductor device where individual circuit devices are patterned in the semiconductor material.

As used herein, the term “vertical” describes an orientation that is arranged perpendicular to the first surface of a chip, chip carrier, chip substrate, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together. The phrase “electrically connected” does not necessarily mean that the elements must be directly in physical contact together-intervening elements may be provided between the “connected” or “electrically connected” elements.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. Nor does describing an element as “first” or “second”, etc. necessarily mean that there is an order or priority to any of the elements. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope. It should be appreciated that the figures and/or drawings accompanying this disclosure are exemplary, non-limiting, and not necessarily drawn to scale.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

### Definitions

Mandrel: A linear or ridge-like projection formed on a substrate. In the subject disclosure, a mandrel defines one of the lines on which an interconnect is formed in an underlying layer.

Self-aligned: The patterning of a structure relative to alignment with another structure.

Sacrificial: A structure formed as a placeholder feature that will be removed to define a new or different feature.

Substrate: Reference to a substrate may refer to material that provides a support structure to features in or on top of the substrate material. As used below, there may be more than one substrate present in an embodiment shown. Also, since embodiments below are generally shown in cross-section, it should be understood that a substrate for a layer with patterned features may not be visible in the view so as to highlight the features for the layer.

Silicon-based: Reference to silicon-based means that a material is comprised at least partly of silicon or can be wholly silicon.

### Example Methodology of Manufacture

In the following, a process describes a general method of forming a semiconductor device with a pillar-based mandrel cut that mitigates doping in a semiconductor channel leading to steeper junction-profile and improved device performance. The fabrication of the devices described herein below can comprise multi-step sequences of, for example, photolithographic and/or chemical processing steps that facilitate gradual creation of electronic-based systems, devices, components, and/or circuits in a semiconducting and/or a superconducting device (e.g., an integrated circuit). For instance, the subject device can be fabricated on one or more substrates (e.g., a silicon (Si) substrates, and/or another substrate) by employing techniques including, but not limited to: photolithography, microlithography, nanolithography, nanoimprint lithography, photomasking techniques, patterning techniques, photoresist techniques (e.g., positive-tone photoresist, negative-tone photoresist, hybrid-tone photoresist, and/or another photoresist technique), etching techniques (e.g., reactive ion etching (RIE), dry etching, wet etching, ion beam etching, plasma etching, laser ablation, and/or another etching technique), evaporation techniques, sputtering techniques, plasma ashing techniques, thermal treatments (e.g., rapid thermal anneal, furnace anneals, thermal oxidation, and/or another thermal treatment), chemical vapor deposition (CVD), atomic layer deposition (ALD), physical vapor deposition (PVD), molecular beam epitaxy (MBE), electrochemical deposition (ECD), chemical-mechanical planarization (CMP), backgrinding techniques, and/or another technique for fabricating an integrated circuit.

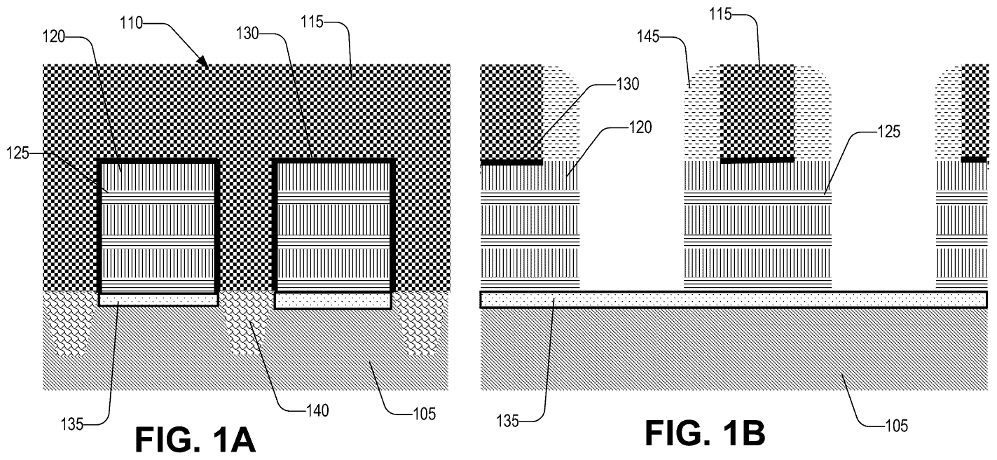

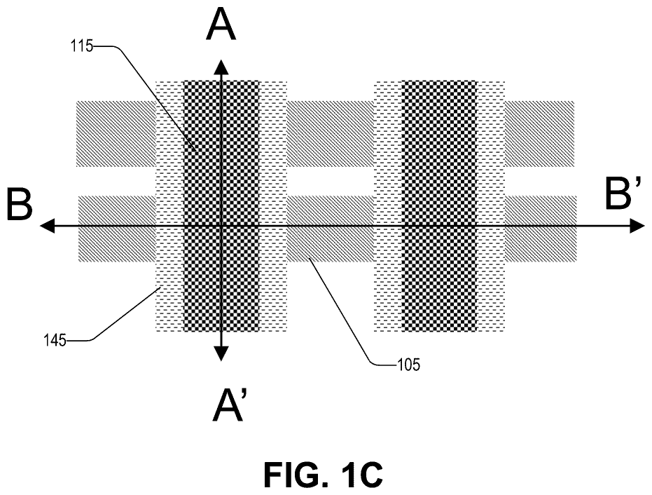

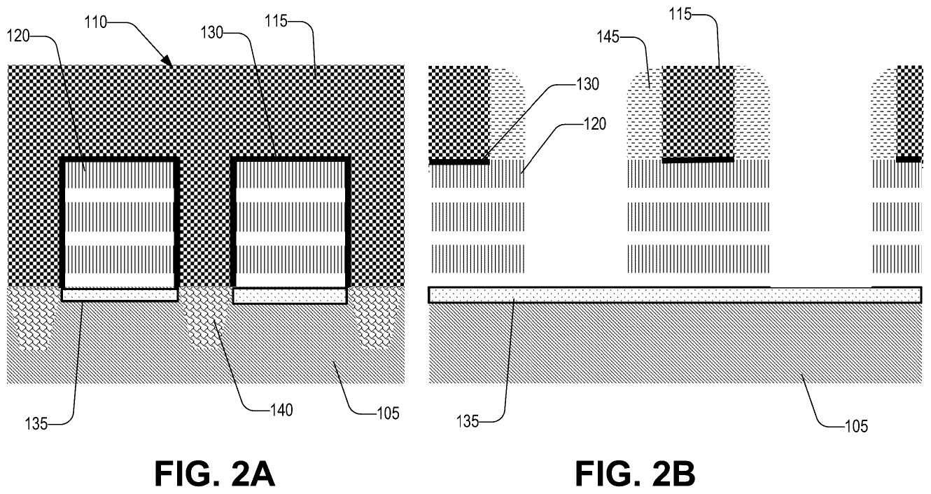

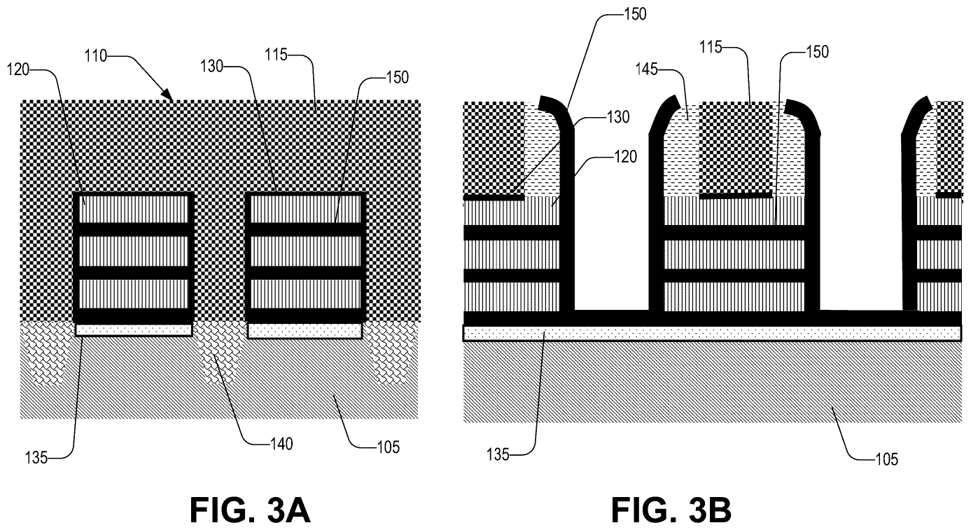

In the description that follows, reference is made to a device under process 110 that is constantly being modified from an initial structure that is shown in FIGS. 1A and 1B. The initial structure is an arbitrary starting point and it should be understood that embodiments of the process may begin at any point prior to the formation shown in FIGS. 1A and 1B, and in some embodiments, may begin at either FIGS. 2A and 2B or 3A and 3B. In addition, FIG. 1C shows a legend. FIGS. 1A-13A (i.e., 1A, 2A, 3A, etc.) show the perspective across line A-A′ in FIG. 1C. FIGS. 1B-13B (i.e., 1B, 2B, 3B, etc.) show the perspective along B-B′ in FIG. 1C.

FIG. 1A is a cross-sectional schematic view of the device under process 110. There is a base substrate 105 supporting vertically stacked layers of semiconductor channels 120 that are initially wrapped with an oxide layer 130. The stacks of semiconductor channels 120 will define pillars in the end device. The semiconductor channels 120 may be for example, silicon, silicon-based or other suitable semiconductive material. A plurality of sacrificial layers 125 separate the semiconductor channels 120. The sacrificial layers 125 may be for example, silicon germanium. In some embodiments, the thickness of sacrificial layers 125 may be lesser than in conventional sacrificial layer thicknesses. An example range for the sacrificial layers may be from 6 to 10 nanometers. A dummy gate 115 may surround the stacks of semiconductor channels 120. Some embodiments may include a buried insulator (BDI) layer 135 separating the bottom semiconductor channel 120 from the base substrate 105. Some embodiments may include shallow trench isolation areas or features 140 separating (for example, in between) adjacent vertically stacked formations of semiconductor channels 120. Some embodiments may include a spacer material 145 adjacent the dummy gate 115.

In one embodiment, the base substrate 105 may be a bulk semiconductor substrate formed of, for example, silicon, or other types of semiconductor substrate materials that are commonly used in bulk semiconductor fabrication such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys.

FIGS. 2A and 2B show the device under process 110 after releasing the sacrificial layers 125. As can be seen, cavities are formed in the spaces between semiconductor channels 120. This act may prepare the device under process 110 for the insertion of dummy material into the layers between the semiconductor channels 120.

FIGS. 3A and 3B show the device under process 110 after layers of a dummy dielectric fill the cavities between the semiconductor channel 120. In addition, a gate oxide 150 is applied, wrapping around the stacks of semiconductor channels 120. The gate oxide 150 may be approximately 6 to 10 nanometers thick. In some embodiments, all levels of semiconductor channels 120 may be covered by the gate oxide 150. In some embodiments, the dummy dielectric fill maybe the same material as the gate oxide (for example, silicon dioxide). Thus, the same reference numeral is used to point at both the gate oxide and the dummy dielectric fill. In some embodiments, the oxide layer 130 may be the same material as the gate oxide 150, thus explaining why the oxide layer 130 and the gate oxide 150 use the same fill pattern.

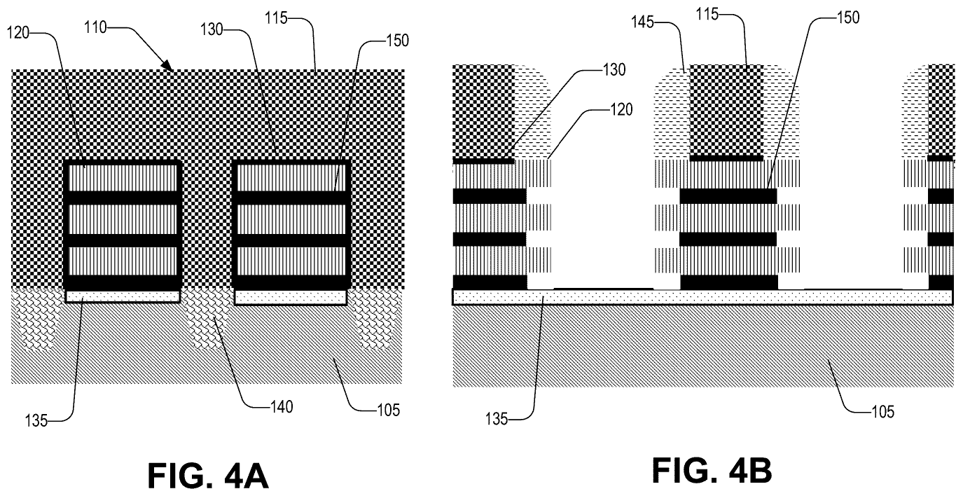

FIGS. 4A and 4B show the device under process 110 after etching the layers of gate oxide 150 and dummy dielectric fill inward from a space between the vertically stacked formations of semiconductor channels 120. The etching forms pockets near the edges, between the layers of semiconductor channels 120.

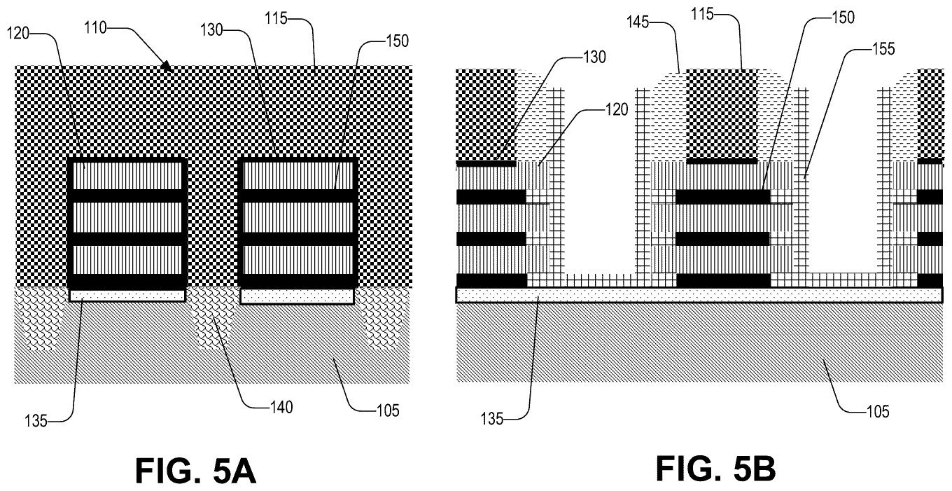

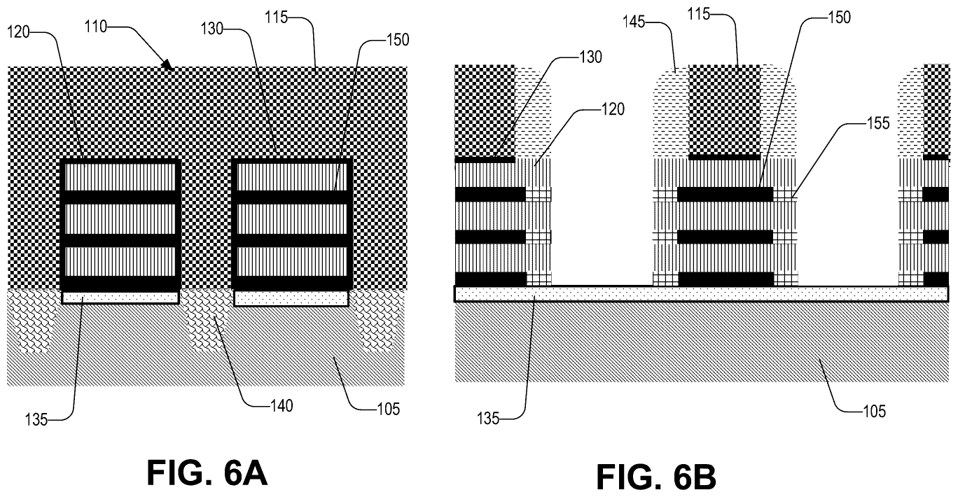

FIGS. 5A and 5B show the device under process 110 after depositing a dielectric inner spacer 155 into the pockets. The deposition may use a conformal technique so that the dielectric inner spacer 155 also covers along the side walls of the pillars where the gate oxide 150 previously resided. In FIGS. 6A and 6B, the process may etch back the inner spacer 155 from the side walls of the pillars leaving a plurality of instances of dielectric inner spacers 155 only in the pockets between the semiconductor channels 120.

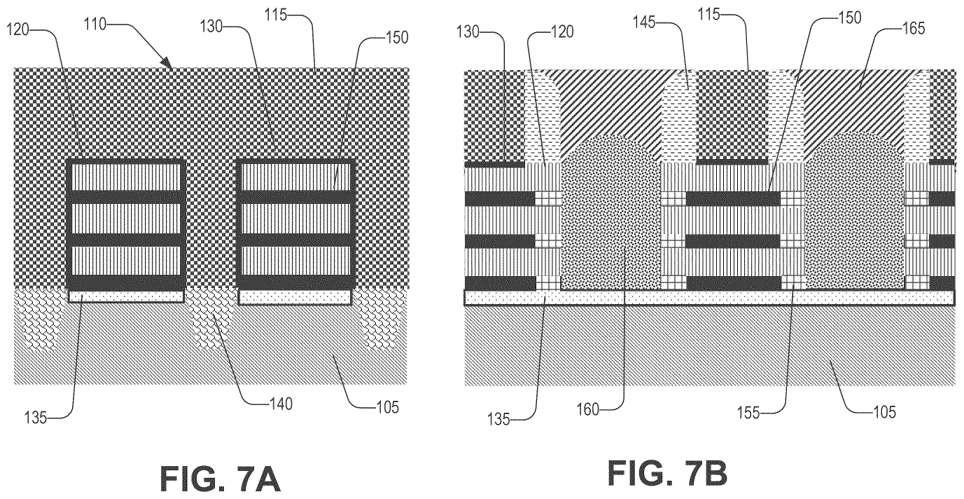

FIGS. 7A and 7B, the show the device under process 110 after source and drain 160 epitaxial deposition into the space between pillars. The source and drain 160 may comprise any dopant material depending on the application. In one embodiment, the source and drain 160 may be a boron-doped silicon-germanium epitaxy for PFET structures. For an NFET structure, the epitaxy may be for example, silicon-phosphorus. The epitaxial growth and any subsequent thermal step will drive in the dopants from the source and drain 160 into the semiconductor channels 120. However, with the gate oxide in place wrapping the silicon channels 120, dopants that diffuse out from the source and drain 160 will segregate into the interfaces between silicon and silicon dioxide and assist in achieving lower channel doping and a steeper doping gradient to channel. In some embodiments, an interlayer dielectric 165 may be deposited over the source and drain 160.

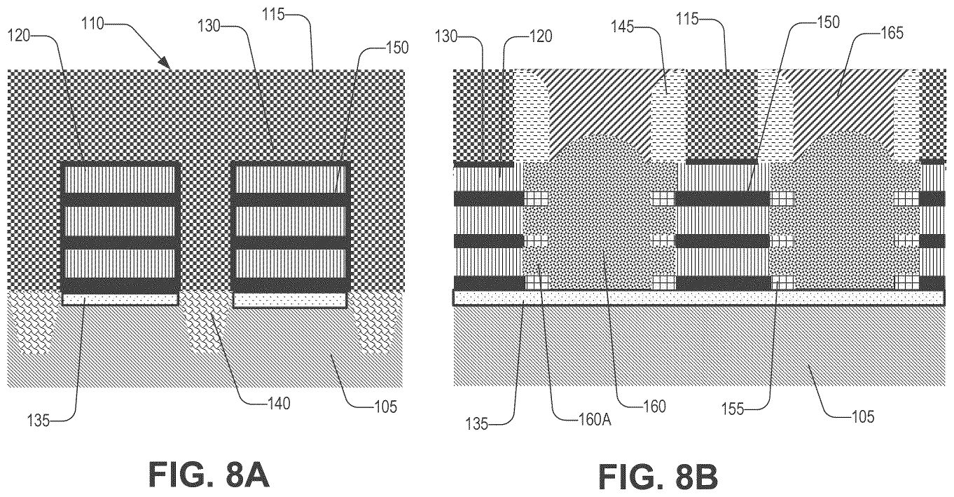

FIGS. 8A and 8B show the device under process 110 after an alternative process step from FIGS. 7A and 7B. In FIGS. 8A and 8B, the source and drain 160 may be diffused partially into the semiconductor channels 120. For example, some of the source and drain 160 material (source and drain extensions 160A) may wrap around some or all of the inner spacer 155 that is present between semiconductor channels 120. By wrapping the source and drain 160 material around the inner spacer 155 material, the region of high doping material is brought closer to the channel region, which contributes to higher device performance.

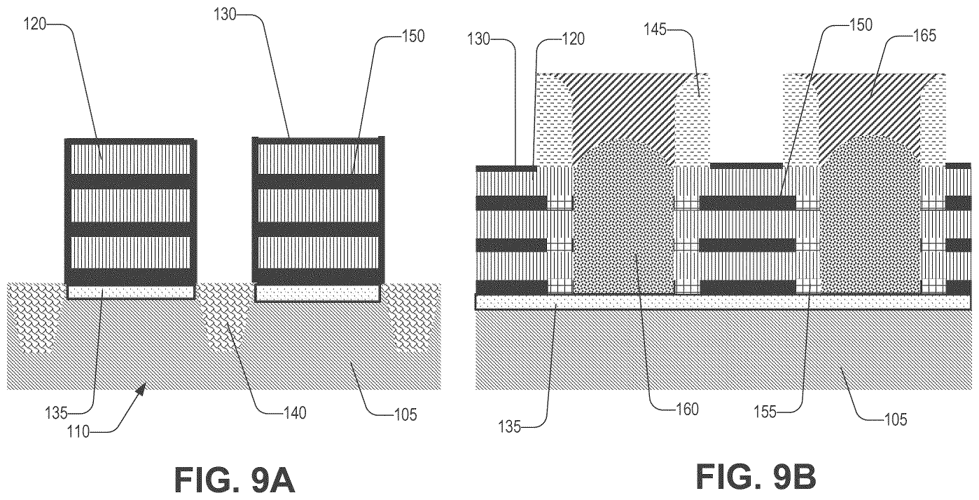

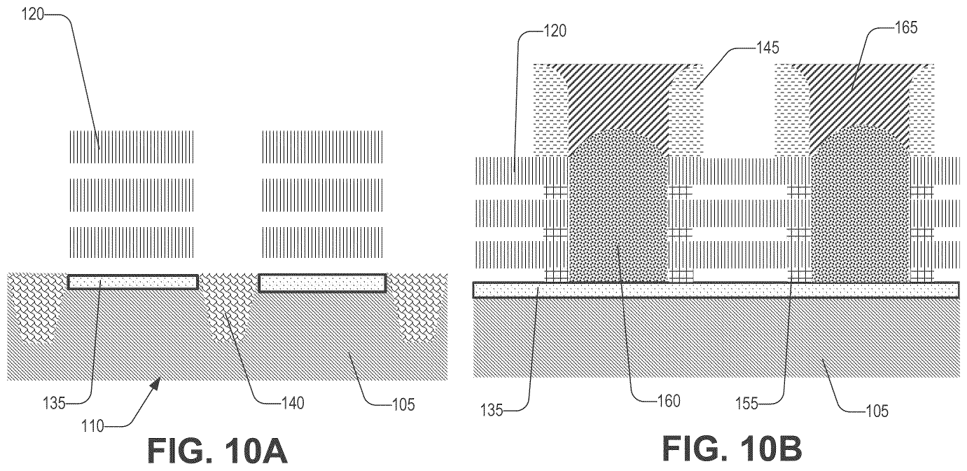

FIGS. 9A and 9B show the device under process 110 after removal of the dummy gate 115. FIGS. 10A and 10B show the device under process 110 after removal of the remaining gate oxide 150 from between the semiconductor channels 120. Removal of the gate oxide 150 is in preparation for depositing the gate material shown further below.

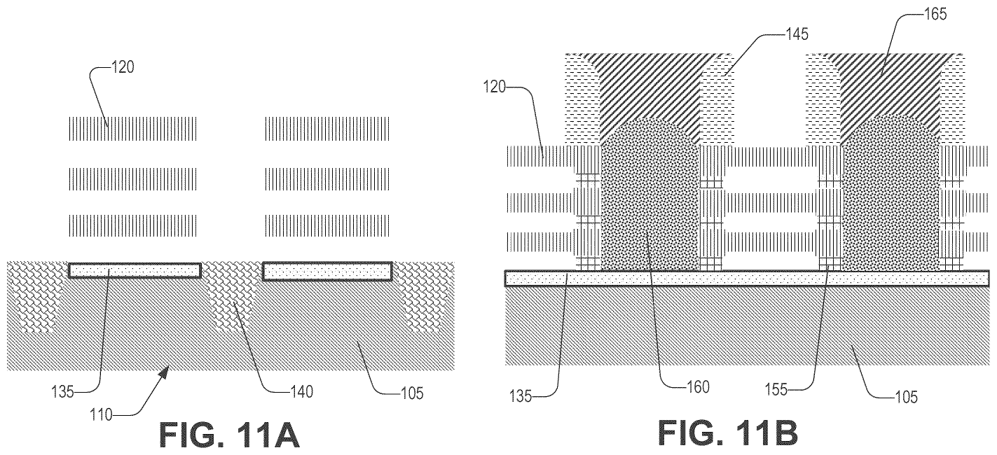

FIGS. 11A and 11B show an embodiment of the device under process 110 after trimming some of the semiconductor channel 120 material. For example, the thickness of one or more silicon layers from semiconductor channels 120 may be reduced after removing the layers of gate oxide 150 and prior to forming the gate. The thickness of silicon may be reduced from one edge of the silicon sheet inward and approximately to the point where the inner spacers 155 are located so that the silicon layer(s) has sections of different thicknesses.

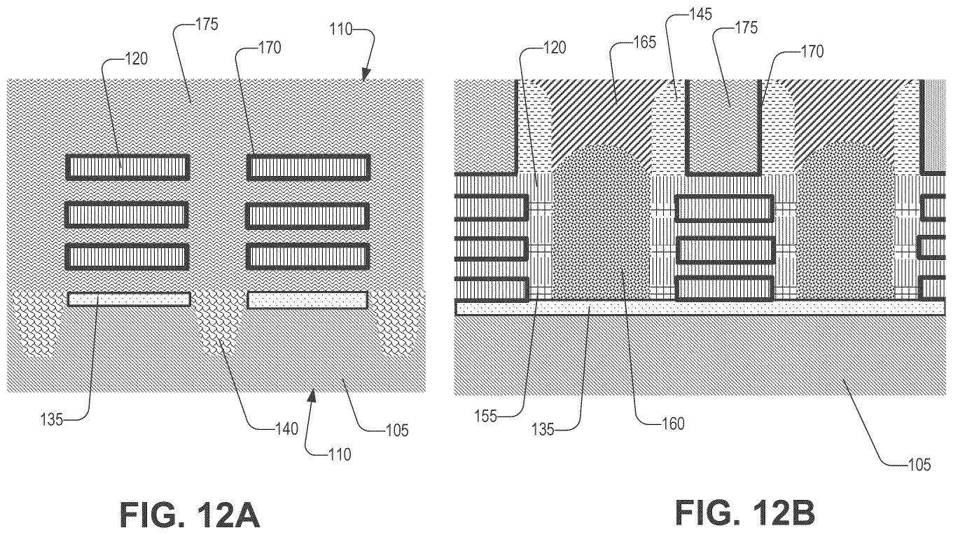

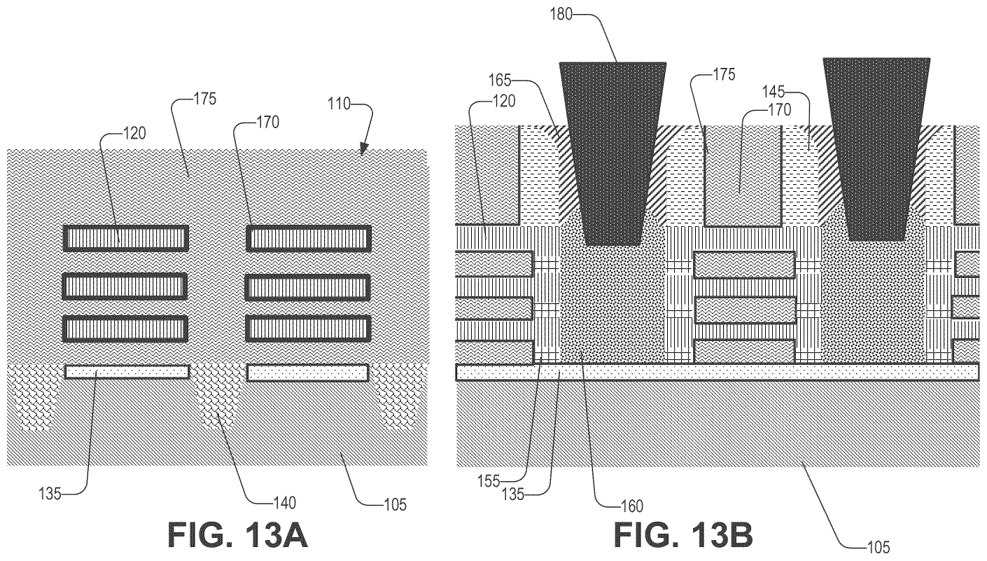

FIGS. 12A and 12B show the device under process 110 formation of the gate 175 around the stacks of semiconductor channels 120. Layers of High-K material 170 may be wrapped around the semiconductor channels 120. The gate 175 may be formed using work-function metal patterning. FIGS. 13A and 13B show the device under process 110 after forming metal contacts 180 in contact with the source and drain 160.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits, and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a substrate;
a source and drain on top of the substrate, wherein the source and drain comprise a doped silicon germanium epitaxy;
a plurality of vertically stacked semiconductor channels positioned adjacent the source and drain; and
a plurality of silicon dioxide layers positioned between the vertically stacked semiconductor channels.

2. The semiconductor device of claim 1, further comprising a plurality of dielectric spacers between the source and drain and respective silicon dioxide layers.

3. The semiconductor device of claim 1, wherein the plurality of silicon dioxide layers wrap around the vertically stacked semiconductor channels.

4. The semiconductor device of claim 1, wherein a boron doped silicon germanium epitaxy is diffused into the vertically stacked semiconductor channels.

5. The semiconductor device of claim 4, wherein the diffusion of doped silicon germanium epitaxy into the vertically stacked semiconductor channels is partially above and below the plurality of silicon dioxide layers.

6. The semiconductor device of claim 1, wherein a thickness of the silicon dioxide layers is between 6 to 10 nanometers.

7. A method of fabricating a semiconductor device, comprising:
providing a semiconductor structure having a plurality of vertically stacked formations including alternating semiconductor layers and sacrificial layers, surrounded by a layer of dummy gate material;
removing the sacrificial layers from the vertically stacked formations and leaving empty channels between the semiconductor layers;
depositing layers of a gate oxide in the empty channels, wherein each layer of the gate oxide wraps around the semiconductor layers;
etching the layers of gate oxide inward from a space between the vertically stacked formations, forming pockets between the semiconductor layers;
depositing a dielectric spacer into the pockets;
depositing a source and drain formation into the space between the vertically stacked formations;
removing the layer of dummy gate material;
removing the layers of gate oxide; and
forming a gate in contact with the semiconductor layers.

8. The method of claim 7, wherein a material for the source and drain is deposited wrapped around the dielectric spacer deposited into the pockets.

9. The method of claim 8, wherein the material for the source and drain is a boron doped silicon germanium epitaxy.

10. The method of claim 7, wherein the layers of gate oxide are silicon dioxide.

11. The method of claim 7, further comprising reducing a thickness of at least one semiconductor layer after removing the layers of gate oxide and prior to forming the gate.

12. The method of claim 11, wherein the thickness of the at least one semiconductor layer is reduced up to the dielectric spacer deposited into the pockets and the at least one semiconductor layer has sections of different thicknesses.

13. The method of claim 7, wherein a thickness of the sacrificial layers is between 6 to 10 nanometers.

14. The method of claim 7, wherein the gate wraps around the semiconductor layers.

15. The method of claim 7, further comprising forming a shallow trench isolation feature in between adjacent vertically stacked formations.

16. A method of controlling a flow of dopants into channels of a semiconductor device, comprising:
providing a semiconductor structure having a sheet of a plurality of vertically stacked formations including a plurality of semiconductor channels and sacrificial material wrapped around the semiconductor channels;
removing the sacrificial material from the sheet and leaving empty channels between the semiconductor channels;
depositing layers of a gate oxide into the empty channels, wherein the gate oxide wraps around the semiconductor channels in the sheet; and
depositing a source and drain epitaxy into a space between the vertically stacked formations, wherein the source and drain epitaxy includes a dopant and a rate of diffusion of the dopant into the semiconductor channels is slowed by a presence of the gate oxide.

17. The method of claim 16, further comprising:
etching the layers of gate oxide inward from a space between the vertically stacked formations, forming pockets between the plurality of semiconductor channels; and
depositing a dielectric spacer into the pockets.

18. The method of claim 17, wherein the source and drain epitaxy is deposited wrapped around the dielectric spacer deposited into the pockets.

19. The method of claim 16, wherein a material for the source and drain epitaxy is silicon germanium epitaxy and the dopant is boron.

20. The method of claim 19, wherein the gate oxide is silicon dioxide.
